(19) United States
(12) Patent Application Publication
(10) Pub. No.: US 2026/0101794 A1
(43) Pub. Date: Apr. 9, 2026

(54) SEMICONDUCTOR MANUFACTURING APPARATUS AND METHOD OF OPERATING THE SAME

(71) Applicant: Samsung Electronics Co., Ltd., Suwon-si (KR)

(72) Inventors: Yongjin PARK, Suwon-si (KR); Jin-San JUNG, Suwon-si (KR); Jaein HEO, Suwon-si (KR); Jihwan HWANG, Suwon-si (KR)

(73) Assignee: Samsung Electronics Co., Ltd., Suwon-si (KR)

(21) Appl. No.: 19/186,987

(22) Filed: Apr. 23, 2025

(30) Foreign Application Priority Data
Oct. 8, 2024 (KR) 10-2024-0136945

(51) Int. Cl. H01L 23/00; H10N 30/20

(52) U.S. Cl. CPC H10W 72/0711; H10W 72/072; H10N 30/20; H10W 72/01271; H10W 72/07118; H10W 72/07236; H10W 72/241

(57) ABSTRACT

A semiconductor manufacturing apparatus includes a flux container defining an accommodation space, the accommodation space configured to accommodate flux, a head tool configured to pick up and position a semiconductor device, semiconductor device including a connection terminal, and a vibration generator configured to apply vibrations to the flux container.

### CROSS-REFERENCE TO RELATED APPLICATION(S)

This U.S. non-provisional application claims priority under 35 USC § 119 to Korean Patent Application No. 10-2024-0136945, filed on Oct. 8, 2024, in the Korean Intellectual Property Office, the disclosure of which is herein incorporated by reference in its entirety.

### BACKGROUND

Example embodiments relate to a semiconductor manufacturing apparatus and a method of operating the same and, more particularly, to a semiconductor manufacturing apparatus for applying flux to a connection terminal of a semiconductor device and a method of operating the same.

Semiconductor devices may be implemented in a semiconductor package to be applied to electronic products. For example, connection terminals may be formed on one side of a semiconductor device, and the semiconductor device may be mounted on a package substrate through the connection terminals. Before mounting the semiconductor device on the package substrate, flux may be applied to surfaces of the connection terminals. As semiconductor devices achieve higher levels of integration, the number of connection terminals may increase, while the heights of the semiconductor devices may decrease. Accordingly, flux may not be uniformly applied to the surfaces of the connection terminals, resulting in various defects. Therefore, research into various methods for achieving uniform flux application is underway.

### SUMMARY

Example embodiments provide a semiconductor manufacturing apparatus for uniformly applying flux to a connection terminal of a semiconductor device and a method of operating the same.

According to at least one example embodiment, a semiconductor manufacturing apparatus includes a flux container defining an accommodation space, the accommodation space configured to accommodate flux; a head tool configured to pick up and position a semiconductor device; and a vibration generator configured to apply vibrations to the flux container.

According to at least one example embodiment, a semiconductor manufacturing apparatus includes a flux container configured to accommodate flux; a vibration generator coupled to the flux container and configured to apply vibrations to the flux container; a transfer head configured to temporarily accommodate the semiconductor device; a stage configured to accommodate a base substrate; and a head tool configured to pick up the semiconductor device from the transfer head and to transfer the semiconductor device between the transfer head, the flux container, and the stage.

According to at least one example embodiment, a method of operating a semiconductor manufacturing apparatus includes supplying flux to an accommodation space of a flux container, applying vibrations to the flux using a vibration generator coupled to the flux container, dipping a connection terminal of a semiconductor device into the vibrating flux, and mounting the dipped semiconductor device on a base substrate.

### BRIEF DESCRIPTION OF DRAWINGS

FIG. 1 is a plan view of a semiconductor manufacturing apparatus according to at least one example embodiment.

FIG. 2 is a cross-sectional view taken along line I-I′ of FIG. 1.

FIG. 3 is an enlarged cross-sectional view of a container module of the semiconductor manufacturing apparatus according to at least one example embodiment.

FIG. 4 is an enlarged cross-sectional view of a container module of the semiconductor manufacturing apparatus according to at least one example embodiment.

FIG. 5 is an enlarged cross-sectional view of a container module of the semiconductor manufacturing apparatus according to at least one example embodiment.

FIG. 6 is a plan view of a container module of the semiconductor manufacturing apparatus according to at least one example embodiment.

FIG. 7 is a cross-sectional view taken along line I-I′ of FIG. 6.

FIG. 8 is a cross-sectional view corresponding to line I-I′ of FIG. 6 and illustrating a container module of the semiconductor manufacturing apparatus according to at least one example embodiment.

FIG. 9 is a flowchart illustrating a method of operating a semiconductor manufacturing apparatus according to at least one example embodiment.

FIGS. 10 to 13 are cross-sectional views illustrating a method of operating a semiconductor manufacturing apparatus according to at least one example embodiment.

### DETAILED DESCRIPTION

Hereinafter, example embodiments will be described with reference to the accompanying drawings, wherein like reference numerals refer to like elements throughout. In this regard, the present embodiments may have different forms and should not be construed as being limited to the descriptions set forth herein.

In the drawings, reference numerals ‘DR1,’ ‘DR2,’ and ‘DR3’ may represent a first direction DR1, a second direction DR2, and a third direction DR3, respectively. The first and second directions DR1 and DR2 may intersect each other. For example, the first and second directions DR1 and DR2 may be perpendicular to each other. The third direction DR3 may be perpendicular to both the first and second directions DR1 and DR2. The first, second, and third directions DR1, DR2, and DR3 in the drawings are illustrated for ease of description, and example embodiments are not limited thereto.

Additionally, when the terms “about” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “about” or “substantially,” it will be understood that these values should be construed as including a manufacturing or operational tolerance (e.g., ±10%) around the stated numerical values and/or geometry. Additionally, whenever a range of values is enumerated, the range includes all values within the range as if recorded explicitly clearly, and may further include the boundaries of the range. Accordingly, the range of “X” to “Y” and/or “X or greater and Y or less” includes all values between X and Y, including X and Y. In contrast, the range of “greater than X and less than Y” includes all detectable values between X and Y excluding X and Y.

Also, in the specification, functional elements which process at least one function or operation, may be realized by and/or include processing circuitry such as, hardware, software, or a combination of hardware and software. For example, the processing circuitry may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. Thereby, the initiation, functions, timing, and/or operations of the apparatuses described below may be enabled by the processing circuitry.

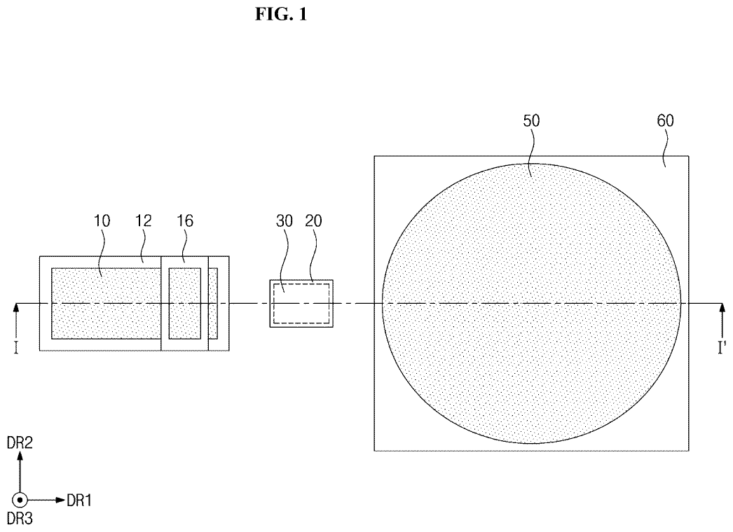

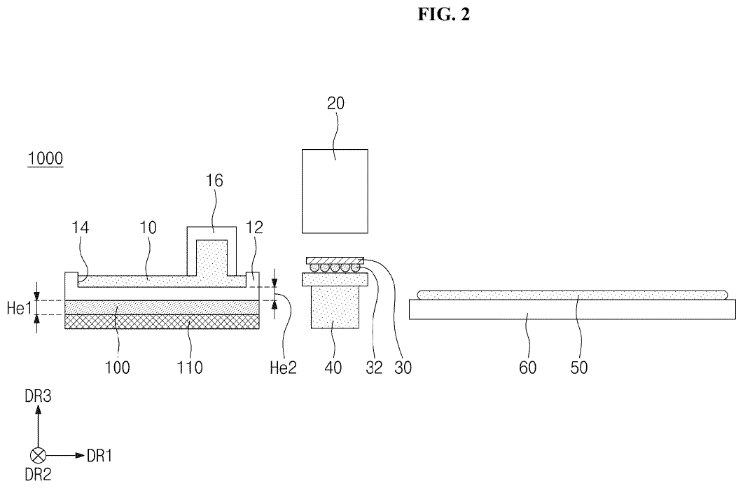

FIG. 1 is a plan view of a semiconductor manufacturing apparatus 1000 according to at least one example embodiment, and FIG. 2 is a cross-sectional view taken along line I-I′ of FIG. 1.

Referring to FIGS. 1 and 2, the semiconductor manufacturing apparatus 1000 according to at least one example embodiment includes a flux container 12, a vibration generator 100, and a head tool 20. The semiconductor manufacturing apparatus 1000 may further include a flux tank 16, a transfer head 40, and a stage 60. The semiconductor manufacturing apparatus 1000 is configured to perform a semiconductor manufacturing process. For example, the semiconductor manufacturing apparatus 1000 may perform a process of dipping connection terminals 32 of a semiconductor device 30 into flux. Also, the semiconductor manufacturing apparatus 1000 may perform a process of mounting the semiconductor device 30 having the dipped connection terminals 32 on a base substrate 50. The semiconductor manufacturing apparatus 1000 may further include (or be connected to) a controller (not illustrated) including processing circuitry configured to control the operation of the semiconductor manufacturing apparatus 1000.

The flux container 12 may have an accommodation space 14 for receiving flux 10. In at least one example embodiment, the accommodation space 14 may be a region recessed from an upper surface of the flux container 12. In at least some embodiments, the bottom surface of the accommodation space 14 may be substantially planar. For example, the accommodation space 14 may have a substantially uniform depth. Although not illustrated, a gauge configured to measure a tilt of the flux container 12 and a device configured to adjust the tilt may be mounted on the flux container 12. The device configured to adjust the tilt may include, for example, one or more of a piston, a motor, an actuator, and/or the like.

The flux 10 is selected to remove oxide layers on the surfaces of the connection terminals 32 of the semiconductor device 30 and to reduce (or prevent) a reaction between atmosphere (or air) and the connection terminals 32 until a subsequent process. In addition, the flux 10 may be configured to remove impurities on the surfaces of the connection terminals 32. For example, the flux 10 may remove oxide layers and impurities on the surfaces of the connection terminals 32 of the semiconductor device 30 thereby facilitating the coupling between the connection terminals 32 of the semiconductor device 30 and pads (or connection terminals) of the base substrate 50 in a subsequent process.

In some embodiments, the flux 10 includes a resin, an activator, and a solvent. The resin may include, for example, at least one of a gum rosin and/or a rosin ester. The activator may further include a nonionic covalent bond organic halide activator. The activator may include, for example, a carboxylic acid. For example, the activator may include, for example, at least one of glutaric acid, adipic acid, or heptanoic acid. The solvent may include at least one of glycol ether ester-based compounds, glycol ether-based compounds, ester-based compounds, ketone-based compounds, cyclic ester-based compounds, propylene glycol monomethyl ether acetate, propylene glycol monomethyl ether, and/or the like.

The flux tank 16 may be configured to supply the flux 10 to the flux container 12. The flux tank 16 may have an internal space for temporarily storing the flux 10. The flux tank 16 may have an outlet, and the flux 10 stored in the internal space of the flux tank 16 may be discharged through the outlet to the accommodation space 14 of the flux container 12. The flux tank 16 may planarized the flux 10 provided in the accommodation space 14 of the flux container 12. For example, the flux tank 16 may planarized the flux 10 in the accommodation space 14 of the flux container 12 while performing a horizontal reciprocating motion. However, the method of supplying and planarizing the flux 10 by the flux tank 16 is not limited thereto.

The vibration generator 100 may be coupled to the flux container 12. The vibration generator 100 may be configured to apply vibrations to the flux container 12. For example, the vibration generator 100 may generate vibrations and apply the generated vibrations to the flux container 12. The vibrations may induce the horizontal reciprocating motion of the flux container 12; thereby the vibration generator 100 may enable the planarization of the flux 10 in the accommodation space 14. In some embodiments, the flux container 12 and the vibration generator 100 may be provided on a support 110. In the present specification, a module including the flux container 12, the vibration generator 100, and the support 110 may be referred to as a “container module.” The flux container 12 and the vibration generator 100 will be described in detail later.

The transfer head 40 may be disposed on one side of the container module. When the semiconductor device 30 is loaded into the semiconductor manufacturing apparatus 1000, the semiconductor device 30 may be temporarily loaded on the transfer head 40. In some embodiments, the semiconductor device 30 may be loaded such that the connection terminals 32 are directed toward an upper surface of the transfer head 40.

The head tool 20 may be configured to pick up the semiconductor device 30. For example, the semiconductor device 30 may be loaded on the transfer head 40, and the head tool 20 may pick up the semiconductor device 30 loaded on the transfer head 40. In some embodiments, the head tool 20 may be configured to be affixed to the semiconductor device 30 using electrostatic force, vacuum pressure, and/or the like, and to pick up the fixed semiconductor device 30. In some embodiments, the upper surface of the semiconductor device 30 may be adhered to a lower surface of the head tool 20 by the electrostatic force, the vacuum pressure, and/or the like. The head tool 20 may move the semiconductor device 30 to one or more desired locations. For example, the head tool 20 may move the semiconductor device 30 onto the flux 10 in the flux container 12 and dip the connection terminals 32 of the semiconductor device 30 into the flux 10. Also, the head tool 20 may move the semiconductor device 30 onto the stage 60 after the flux dip. Although not illustrated, a gauge configured to measure a tilt of the lower surface of the head tool 20 and a device configured to adjust the tilt may be mounted on the head tool 20.

The stage 60 may be disposed on one side of the container module. In at least one example embodiment, the transfer head 40 may be disposed between the container module and the stage 60, as illustrated in the drawings. However, example embodiments are not limited to the locations of the container module, the transfer head 40, and the stage 60 illustrated in FIGS. 1 and 2. The locations of the container module, the transfer head 40, and the stage 60 may be variously changed to efficiently perform the dipping process and the mounting process.

The stage 60 may be configured to accommodate the base substrate 50. For example, the base substrate 50 may be loaded onto an upper surface of the stage 60 during a semiconductor manufacturing process. The stage 60 may be configured to support and/or fix the base substrate 50. For example, the stage 60 may include an electrostatic chuck ESC to fix the base substrate 50 using electrostatic force and/or a vacuum chuck to fix the base substrate 50 using vacuum pressure.

The semiconductor device 30 may include at least one of various types of semiconductor chips. For example, the semiconductor device 30 may include at least one of a memory chip or a logic chip. For example, the memory chip may be (or include) at least one of a dynamic random access memory (DRAM) chip, a static random access memory (SRAM) chip, a phase-change random access memory (PRAM) chip, a magnetoresistive random access memory (MRAM) chip, a flash memory chip, and/or the like. For example, the logic chip may be at least one of a central processing unit, a graphics processing unit, an application-specific integrated circuit (ASIC) chip, an application processor chip and/or the like. In some embodiments, the semiconductor device 30 may include a plurality of stacked memory chips.

The semiconductor device 30 may further include the connection terminals 32 adhered to one surface of the semiconductor device 30. For example, the connection terminals 32 may be adhered to the lower surface of the semiconductor device 30, as illustrated in FIG. 2. In some embodiments, when the semiconductor device 30 includes a memory chip or a logic chip, the connection terminals 32 may be directly adhered to a lower surface of the memory chip or the logic chip. The semiconductor device 30 may be a chip-size package. In some embodiments, when the semiconductor device 30 includes the memory chip and the logic chip, the semiconductor device 30 may further include an interposer on which the memory chip and the logic chip are mounted. The connection terminals 32 may be adhered to a lower surface of the interposer, and the memory chip and the logic chip may be mounted on an upper surface of the interposer.

In some embodiments, the connection terminals 32 may be formed of (or include) a tin-silver-copper alloy, a tin-silver alloy, a tin-copper alloy, and/or the like. For example, the connection terminals 32 may be solder balls or solder bumps, but example embodiments are not limited thereto. Alternatively, the connection terminals 32 may be formed of at least one of other conductive materials. In some embodiments, a width (or diameter) of each of the connection terminals 32 may be several tens to several hundreds of micrometers. In at least some embodiments, the connection terminals 32 may be adhered to a contact pad, of the semiconductor device 30.

The base substrate 50 may be loaded on the upper surface of the stage 60 during the semiconductor manufacturing process. In some embodiments, the base substrate 50 may include a plurality of mounting region and a scribe lane region between the mounting regions. The semiconductor device 30 may be mounted on a corresponding one of the mounting regions during the semiconductor manufacturing process. The connection terminals 32 may be bonded to a corresponding mounting region. The connection terminals 32 may function as electrical signal paths between an internal circuit of the semiconductor device 30 and the corresponding mounting region. In some embodiments, each of the mounting regions may include connection terminals. The connection terminals may include, for example, pads, a under bump metallization layer (UBM), and/or the like connected to the connection terminals 32 and interconnections electrically connected to the pads. In some embodiments, each of the mounting regions may be a package substrate, another semiconductor device, a redistribution substrate, or an interposer. For example, each of the mounting regions may be a printed circuit board (PCB), a semiconductor substrate (for example, a silicon substrate) having the pads and the interconnections, or a glass substrate having the pads and the interconnections. The scribe lane region may be a region to be cut in a subsequent sawing process. In some embodiments, the base substrate 50 may have a circular or rectangular panel shape in plan view. However, the example embodiments are not limited to the base substrate 50 having the above-described structure and shape. The structure, size, and/or shape of the base substrate 50 may vary.

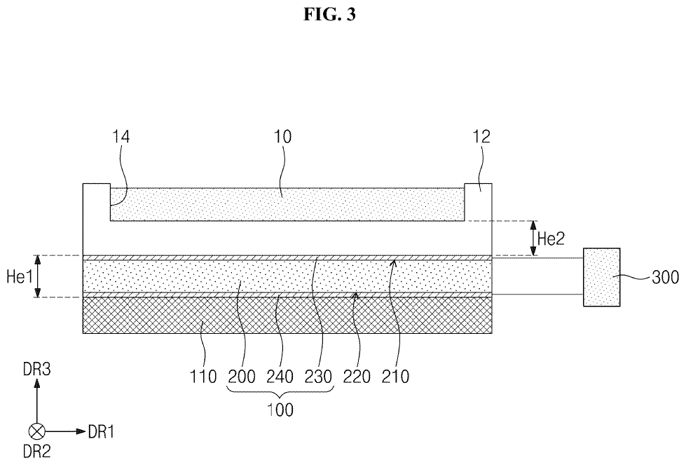

Hereinafter, the container module will be described in more detail with reference to FIG. 3.

FIG. 3 is an enlarged cross-sectional view of a container module of the semiconductor manufacturing apparatus according to at least one example embodiment.

Referring to FIGS. 1, 2, and 3, in some embodiments, the vibration generator 100 may be coupled to a lower surface of the flux container 12. For example, an upper surface of the vibration generator 100 may be coupled to the lower surface of the flux container 12. The vibration generator 100 and the flux container 12 may be sequentially stacked on the support 110. For example, the vibration generator 100 may be disposed between the flux container 12 and the support 110.

In some embodiments, the vibration generator 100 may include a vibration plate 200 having a first surface 210 and a second surface 220 opposing the first surface 210, and a first electrode 230 and a second electrode 240, respectively provided on the first surface 210 and the second surface 220 of the vibration plate 200. The semiconductor manufacturing apparatus 1000 may further include a power supply 300 electrically connected to the vibration generator 100. The vibration plate 200 may be configured to vibrate the flux 10 by transmitting vibrations to the flux container 12. In some embodiments, the vibration plate 200 may be configured to generate ultrasonic waves to apply the vibrations.

According to some embodiments, the vibration plate 200 may be formed of a material that may vibrate due to alternating current applied through the first and second electrodes 230 and 240. For example, the vibration plate 200 may be formed of a piezoelectric. For example, the piezoelectric may have a phase wherein molecules of the piezoelectric function as dipoles and such that the piezoelectric repeatedly contract and expand due to the applied alternating current. Thus, the piezoelectric may vibrate. The power supply 300 may be configured to apply the alternating current to the first and second electrodes 230 and 240. In some embodiments, a frequency of the vibration generated by the vibration plate 200 may be 60 kilohertz (KHz) or more. A frequency of the alternating current may also be 60 KHz or more. However, example embodiments are not limited thereto.

For example, the piezoelectric may be a piezoelectric ceramic and/or may be formed of at least one of zirconia, titanium oxide, lead zirconate titanate (PZT), zinc oxide (ZnO), tin oxide (SnO), ZnSnO₃, and/or polyvinylidene fluoride (PVDF), but example embodiments are not limited thereto. The piezoelectric may be formed of at least one of various other materials. Each of the first and second electrodes 230 and 240 may include at least one of graphene, carbon nanotubes (CNT), indium tin oxide (ITO), metal, and/or conductive polymer, but example embodiments are not limited thereto.

In some embodiments, as illustrated in FIG. 3, the first surface 210 and the second surface 220 of the vibration plate 200 may be an upper surface and a lower surface of the vibration plate 200, respectively. For example, the first surface 210 of the vibration plate 200 may be directed toward the flux container 12, and the second surface 220 of the vibration plate 200 may be directed toward the support 110. The vibration plate 200 may vertically vibrate due to the alternating current.

In some embodiments, a height He1 of the vibration generator 100 may be substantially equal to or greater than a height He2 from a lower surface of the flux container 12 to a bottom surface of the accommodation space 14. Accordingly, the vibrations generated by the vibration generator 100 may be easily and efficiently transmitted to the flux 10 supplied in the flux container 12. When the first and second electrodes 230 and 240 are respectively provided on the upper surface and the lower surface of the vibration plate 200, the height He1 of the vibration generator 100 may be defined as a vertical distance from a lower surface of the second electrode 240 to an upper surface of the first electrode 230, as illustrated in FIG. 3.

According to the above-described embodiments, the vibration generator 100 may be configured to apply vibrations to the flux container 12. Thus, the vibration generator 100 may apply vibrations to the flux 10 supplied in the flux container 12. As a result, the flux 10 may be applied substantially uniformly to the surfaces of the connection terminals 32 of the semiconductor device 30 during the dipping process. More specifically, even when the lower surface of the head tool 20 and the bottom surface of the accommodation space 14 are adjusted to be horizontal by gauges and tilt adjustment devices, the upper surface of the flux 10 and/or the connection terminals 32 may be tilted and thereby the flux 10 may not be uniformly applied to at least one surface of the connection terminals 32. This non-uniform application may cause poor contact between the connection terminal and the mounting region of the base substrate. However, according to the example embodiments, the vibration generator 100 may vibrate the flux 10 and the connection terminals 32 may be dipped into the vibrating flux 10. Accordingly, the flux 10 may be applied substantially uniformly to the surfaces of the connection terminals 32. For example, the vibration generator 100 may improve the uniformity of the flux application. As a result, poor contact may be mitigated or prevented.

In FIG. 3, the vibration generator 100 may be coupled to the lower surface of the flux container 12, but example embodiments are not limited thereto. In some embodiments, the vibration generator 100 may be provided within the flux container 12. This will be described in detail below.

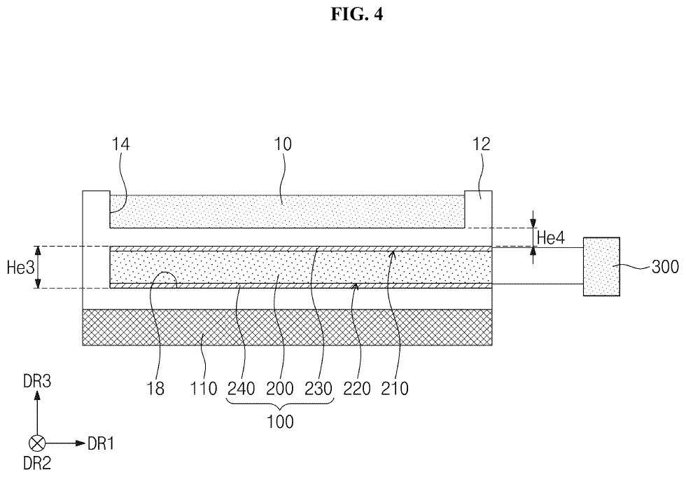

FIG. 4 is an enlarged cross-sectional view of a container module of the semiconductor manufacturing apparatus according to at least one example embodiment.

Referring to FIG. 4, in some embodiments, the vibration generator 100 may be provided within an internal space 18 defined in the flux container 12. In some embodiments, the internal space 18 may be a region recessed from a side surface of the flux container 12, as illustrated in the drawing. However, example embodiments are not limited thereto, and a shape of the internal space 18 may vary. In some embodiments, a height He3 of the vibration generator 100 may be substantially equal to or greater than a height He4 from an upper surface of the vibration generator 100 to a bottom surface of the accommodation space 14 of the flux container 12. The height He4 may be a height of a portion of the flux container 12 disposed above the vibration generator 100 and below the bottom surface of the accommodation space 14.

Referring to FIGS. 3 and 4, in some embodiments, a single vibration generator 100 may overlap the entire bottom surface of the accommodation space 14. Thus, the single vibration generator 100 may apply vibrations of the same frequency to the entire flux 10 provided in the accommodation space 14.

In FIGS. 3 and 4, first and second surfaces 210 and 220 of the vibration plate 200 may be the upper surface and the lower surface of the vibration plate 200, respectively. However, example embodiments are not limited thereto. In some embodiments, the first and second surfaces 210 and 220 of the vibration plate 200 may be other surfaces of the vibration plate 200. This will be described in detail below.

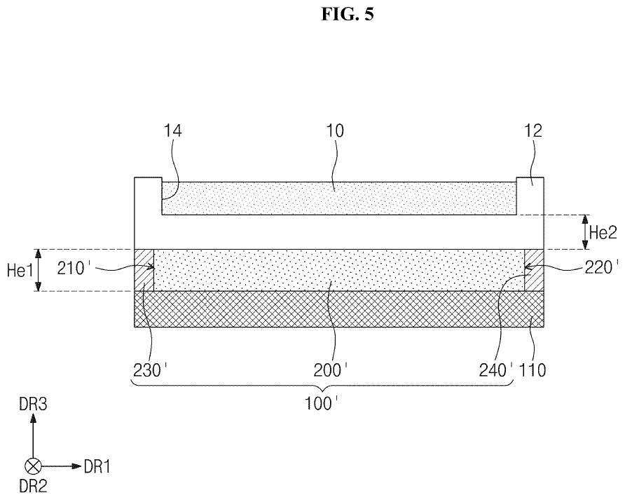

FIG. 5 is an enlarged cross-sectional view of a container module of the semiconductor manufacturing apparatus according to at least one example embodiment.

Referring to FIG. 5, the vibration generator 100′ may include a vibration plate 200′, a first electrode 230′, and a second electrode 240′, and first and second surfaces 210′ and 220′ of the vibration plate 200′ may be both side surfaces of the vibration plate 200′. The side surfaces of the vibration plate 200′ may oppose each other. The first electrode 230′ and the second electrode 240′ may be provided on the first and second surfaces 210′, 220′ (for example, the side surfaces of the vibration plate 200′), respectively. The first and second electrodes 230′, 240′ may be electrically connected to a power supply 300 (see FIG. 3). The vibration plate 200′ may vibrate horizontally due to alternating current applied through the first and second electrodes 230′ and 240′.

In the present example, a height He1 of the vibration generator 100′ may correspond to a height (or thickness) of the vibration plate 200′. The height He1 of the vibration generator 100′ may be substantially equal to or greater than a height He2 from an upper surface of the vibration plate 200′ to a bottom surface of the accommodation space 14 of the flux container 12.

In the present example, the single vibration generator 100′ may cover the entire bottom surface of the accommodation space 14. Thus, the vibration generator 100′ may apply vibrations of the same frequency to the entire flux 10.

In the above-described embodiments, the single vibration generator 100′ may cover the entire bottom surface of the accommodation space 14. However, example embodiments are not limited thereto.

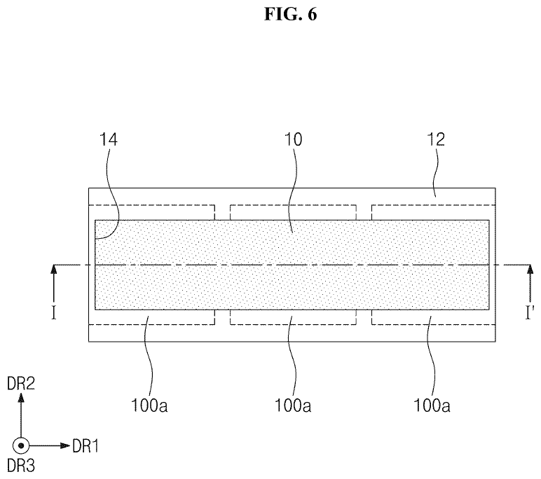

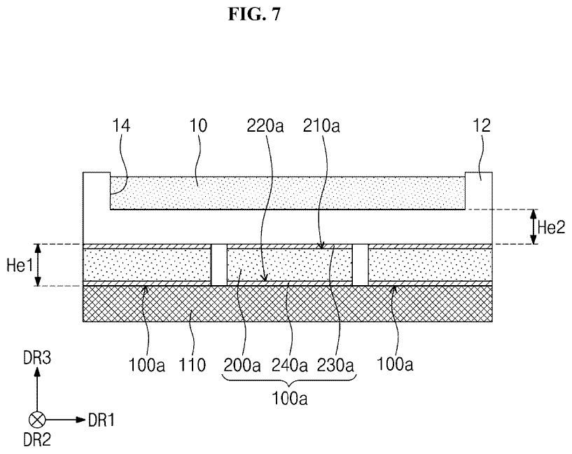

FIG. 6 is a plan view of a container module of the semiconductor manufacturing apparatus according to at least one example embodiment, and FIG. 7 is a cross-sectional view taken along line I-I′ of FIG. 6.

Referring to FIGS. 6 and 7, a vibration generator may be provided in plurality. A plurality of vibration generators 100a may be two-dimensionally arranged in at least one of a horizontal direction (e.g., the first and/or the second directions DR1 and DR2) and/or parallel to a bottom surface of the accommodation space 14 of the flux container 12.

In FIG. 7, the vibration generators 100a may be arranged in the first direction DR1, but example embodiments are not limited thereto. In some embodiments, the vibration generators 100a may be arranged in the second direction DR2 or may be arranged in a matrix in the first and second directions DR1 and DR2.

The bottom surface of the accommodation space 14 may be divided into a plurality of regions. The divided regions of the bottom surface of the accommodation space 14 may correspond to the vibration generators 100a, respectively. For example, the vibration generators 100a may cover the divided regions of the bottom surface of the accommodation space 14, respectively. Therefore, the divided regions of the bottom surface of the accommodation space 14 may be arranged in at least one of the first and second directions DR1 and DR2. In some embodiments, the sum of planar areas of the plurality of vibration generators 100a may be larger or smaller than a planar area of the bottom surface of the accommodation space 14. In contrast, the sum of the planar areas of the plurality of vibration generators 100a may be substantially the same as the planar area of the bottom surface of the accommodation space 14.

As illustrated in FIG. 7, each of the vibration generators 100a may include a vibration plate 200a, a first electrode 230a, and a second electrode 240a. The first and second electrodes 230a and 240a may be provided on the first and second surfaces 210a and 220a, opposing each other, of the vibration plate 200a, respectively. In some embodiments, as illustrated in FIG. 7, the first and second surfaces 210a and 220a of the vibration plate 200a may be upper and lower surfaces of the vibration plate 200a, respectively. The vibration plate 200a may be formed of the same material as the vibration plate 200 described with reference to FIG. 3. Each of the first and second electrodes 230a and 240a may be formed of the same material as the first and second electrodes 230 and 240 described with reference to FIG. 3.

In some embodiments, the plurality of vibration generators 100a may be configured to be controlled independently of each other. In some embodiments, the vibration plates 200a of the plurality of vibration generators 100a may be configured to vibrate at different frequencies. For example, alternating currents of different frequencies may be applied to the vibration generators 100a, respectively. Thus, the vibration plates 200a of the vibration generators 100a may vibrate at different frequencies. As a result, each of the divided regions may be applied with vibration of a desired frequency.

Density of connection terminals 32 on one region of the lower surface of the semiconductor device 30 may be different from density of connection terminals 32 on another region of the lower surface of the semiconductor device 30. In addition, some of the connection terminals 32 may be disposed on a central portion of the lower surface of the semiconductor device 30, and other connection terminals 32 may be disposed on an edge portion of the lower surface of the semiconductor device 30. Such a difference in the density of the connection terminals 32 and/or difference in the positions of the connection terminals 32 may cause a difference in the amount of flux applied to the connection terminals 32. According to the present example, the plurality of vibration generators 100a may cover the divided regions of the bottom surface of the accommodation space 14, respectively, and may be controlled independently of each other. Accordingly, the plurality of vibration generators 100a may apply vibrations having appropriate frequencies to the divided regions, respectively. As a result, the difference in the amount of flux applied to the connection terminals 32 may be significantly reduced or prevented, allowing the flux 10 to be uniformly applied to the surfaces of the connection terminals 32.

In some embodiments, the power supply 300 (see FIG. 3) may be provided in plural such that the vibration generators 100a are controlled independently of each other. The plurality of power supplies 300 may be electrically connected to the plurality of vibration generators 100a, respectively.

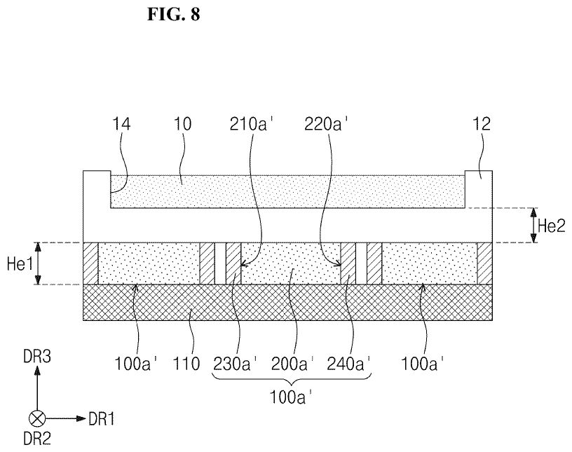

FIG. 8 is a cross-sectional view corresponding to line I-I′ of FIG. 6 and illustrating a container module of the semiconductor manufacturing apparatus according to at least one example embodiment.

Referring to FIG. 8, vibration generators 100a′ may each include a vibration plate 200a′, a first electrode 230a′, and a second electrode 240a′. The first and second electrodes 230a′ and 240a′ may be provided on first and second surfaces 210a′ and 220a′, opposing each other, of the vibration plate 200a′, respectively. In the present example, the first and second surfaces 210a′ and 220a′ of the vibration plate 200a′ may be both side surfaces, opposing each other, of the vibration plate 200a′. Accordingly, the vibration plate 200a′ may vibrate horizontally.

Other features of the semiconductor manufacturing apparatus according to the present example may be the same as and/or substantially similar to corresponding features of the semiconductor manufacturing apparatus of FIG. 7.

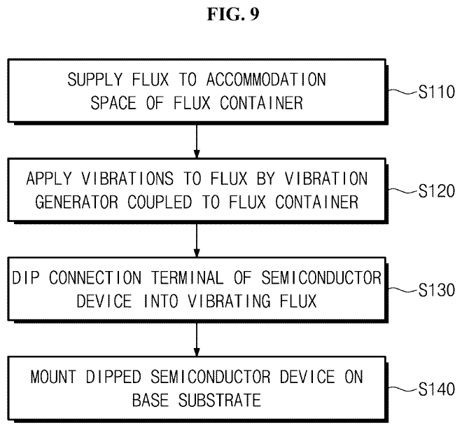

FIG. 9 is a flowchart illustrating a method of operating a semiconductor manufacturing apparatus 1000 according to at least one example embodiment.

Referring to FIG. 9, the method of operation the semiconductor manufacturing apparatus 1000 (hereinafter referred to as the “operating method”) may include supplying flux to the accommodation space of the flux container (S110), applying vibrations to the flux by the vibration generator coupled to the flux container (S120), dipping the connection terminal of the semiconductor device into the vibrating flux (S130), and mounting the dipped semiconductor device on the base substrate (S140).

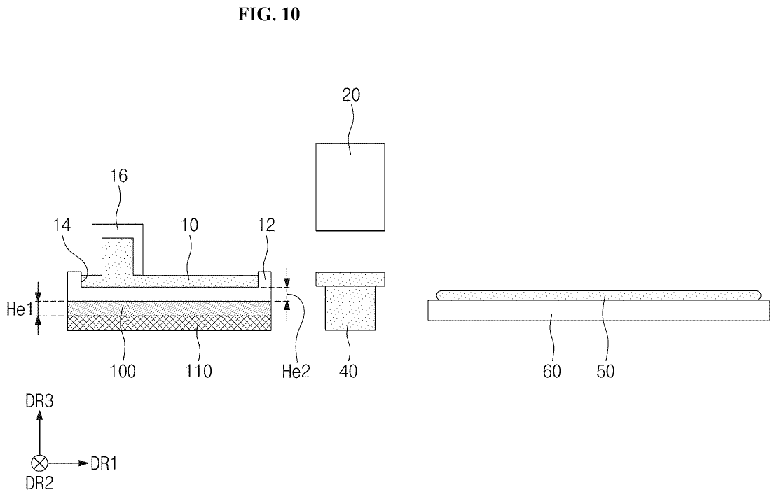

Hereinafter, the operating method will be described in more detail with reference to FIGS. 10 to 13.

FIGS. 10 to 13 are cross-sectional views illustrating a method of operating a semiconductor manufacturing apparatus according to at least one example embodiment.

Referring to FIGS. 9 and 10, in operation S110, the flux 10 may be supplied to the accommodation space 14 of the flux container 12. For example, the flux 10 in the flux tank 16 may be supplied to the accommodation space 14 through an outlet of the flux tank 16. In at least one example, the flux 10 may be extruded from the outlet of the flux tank 16. The flux tank 16 may supply the flux 10 to the accommodation space 14 and planarize the supplied flux 10 while performing a horizontal reciprocating motion. In at least some embodiments, the flux tank 16 may be repositioned after the flux 10 is supplied. The base substrate 50 may be loaded on the stage 60. The loading of the base substrate 50 may be performed before or after operation S110, but example embodiments are not limited thereto. The order of loading the base substrate 50 may vary before operation S140.

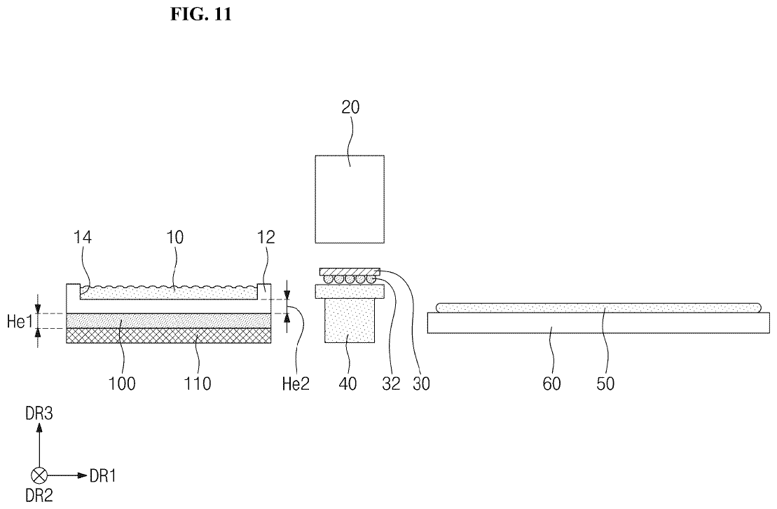

Referring to FIGS. 9 and 11, in operation S120, vibrations may be applied to the flux 10 in the accommodation space 14 by the vibration generator 100. For example, an alternating current may be applied to the vibration generator 100 (for example, the first and second electrodes 230 and 240, see FIG. 3) by the power supply 300 (see FIG. 3). Accordingly, the vibration generator 100 (for example, the vibration plate 200, see FIG. 3) may generate the vibration. The generated vibration may be applied to the flux 10 through the flux container 12. As a result, the flux 10 may vibrate. For example, the vibration plate 200 (see FIG. 3) may generate ultrasonic waves, and the ultrasonic waves may be applied to the flux 10 through the flux container 12 to vibrate the flux 10.

The semiconductor device 30 may be positioned or loaded on the transfer head 40. The connection terminals 32 of the semiconductor device may be directed toward the transfer head 40 and may be seated on the transfer head 40. Positioning and/or loading the semiconductor device 30 on the transfer head 40 may be performed before supplying the flux 10 to the accommodation space 14 (S110), but example embodiments are not limited thereto. In at least one example embodiment, positioning and/or loading the semiconductor device 30 on the transfer head 40 may be performed between supplying the flux 10 to the accommodation space 14 (S110) and applying vibrations to the flux 10 by the vibration generator 100 (S120). In contrast, positioning and/or loading the semiconductor device 30 on the transfer head 40 may be performed after operation S110 and operation S120.

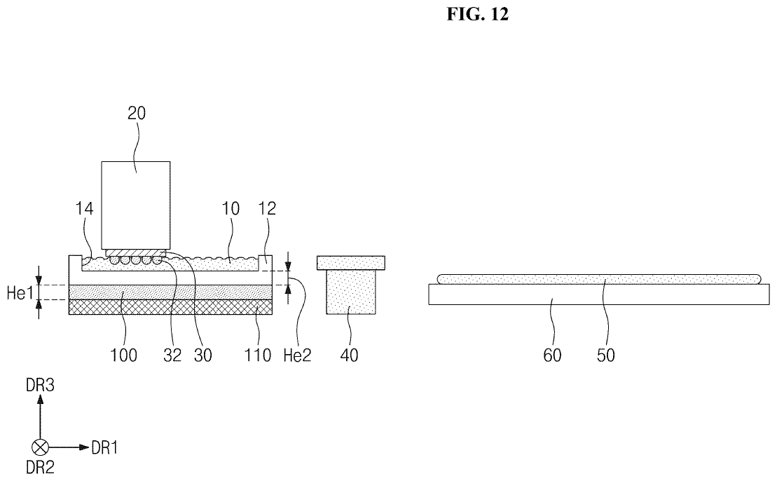

Referring to FIGS. 9 and 12, in operation S130, the connection terminals 32 of the semiconductor device 30 may be dipped into the vibrating flux 10. For example, the head tool 20 may pick up the semiconductor device 30, loaded on the transfer head 40, using vacuum pressure and/or electrostatic force and move the picked-up semiconductor device 30 over the flux container 12. Then, the head tool 20 may dip the connection terminals 32 of the semiconductor device 30 into the vibrating flux 10. According to some example embodiments, the connection terminals 32 may be dipped into the vibrating flux 10. Accordingly, the flux 10 may be applied substantially uniformly to the surfaces of the connection terminals 32. In comparative examples, even when the head tool 20 and/or the flux container 12 are adjusted such that the lower surface of the head tool 20 and/or the bottom surface of the accommodation space 14 are horizontal, the upper surface of the flux 10 and/or the connection terminals 32 may be tilted. Thus, the flux 10 may not be uniformly applied to at least one surface of the connection terminals 32 in the comparative examples, resulting in poor contact between the connection terminal and the mounting region of the base substrate. However, according to the example embodiments, the flux 10 may be vibrated by the vibration generator 100, and thus, the flux 10 may be applied substantially uniformly to the surfaces of the connection terminals 32. As a result, poor contact may be mitigated or prevented, and reliability of a final semiconductor device (for example, a semiconductor package) may be improved.

In some embodiments, the dipped portion of the connection terminal 32 may account for about 80% or less of a diameter of the connection terminal 32. Accordingly, the semiconductor device 30 may be prevented from detaching from the head tool 20 and/or slipping due to excessive application of the flux 10.

When a plurality of vibration generators 100a or 100a′ of FIG. 7 or FIG. 8 are applied to the container module, applying vibrations to the flux by the vibration generator (S120) may include applying alternating currents of different frequencies to at least two vibration generators, among the vibration generators 100a or 100a′, respectively. Accordingly, a difference in the amount of flux applied to the connection terminals 32, which may be caused by a difference in the density of the connection terminals 32 on the lower surface of the semiconductor device 30 and/or a difference in the positions of the connection terminals 32, may be significantly reduced or eliminated. For example, the frequencies of the vibration generators 100a or 100a′ may be controlled to correspond to the difference in density and/or position of the connection terminals 32, and thus the difference in the amount of flux applied to the connection terminals 32 may be significantly reduced or eliminated. As a result, the flux 10 may be applied substantially uniformly to the surfaces of the connection terminals 32.

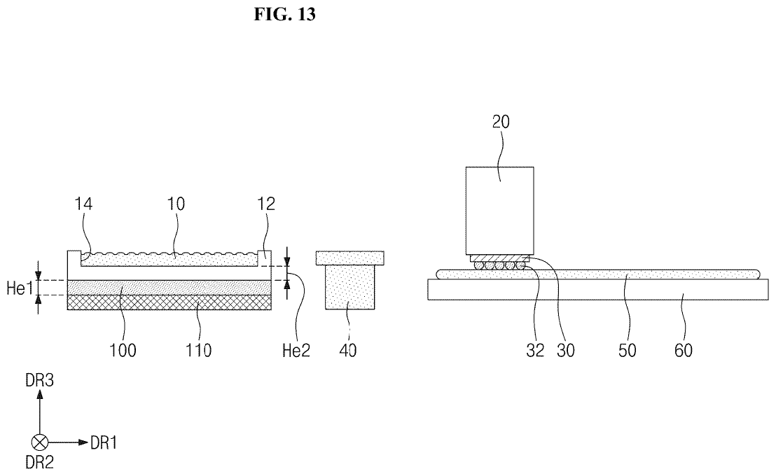

Referring to FIGS. 9 and 13, in operation S140, the dipped semiconductor device 30 may be mounted on the base substrate 50. For example, the head tool 20 may move the dipped semiconductor device 30 over the base substrate 50 and mount the moved semiconductor device 30 on a corresponding mounting region among mounting regions of the base substrate 50.

Operation S130 (dipping) and operation S140 (mounting) may be repeatedly performed using different semiconductor devices. Accordingly, desired semiconductor devices may be mounted on the base substrate 50. Then, the base substrate 50 may be unloaded from the stage 60.

A reflow process may be performed on the unloaded base substrate 50. The reflow process enables the connection terminals 32 of the semiconductor device 30 to be coupled to corresponding pads of the mounting region of the base substrate 50. The flux 10, the connection terminals 32, and the pads of the base substrate 50 may react with each other during the reflow process. Accordingly, an intermetallic compound (IMC) may be formed. The IMC may be a metal compound obtained by the reaction of the connection terminal 32, the pad, and the flux 10. The IMC may improve the bonding strength between the pad and the connection terminal 32. According to the embodiments, the flux 10 is applied substantially uniformly to the surfaces of the connection terminals 32, and thus IMCs between the pads and the connection terminals 32 may be formed to have substantially uniform thicknesses. As a result, the reliability of a final semiconductor device (for example, a semiconductor package) may be improved.

As set forth above, according to the example embodiment, flux may be applied uniformly to connection terminals of a semiconductor device by a vibration generator generating vibrations. Accordingly, poor contact between the connection terminal and the base substrate may be prevented.

In addition, according to the example embodiments, vibrations of different frequencies may be applied to divided regions of a flux container, respectively. Accordingly, insufficient application (or under-application) of flux may be prevented in a specific region of the flux container.

In addition, according to the example embodiments, a depth of flux accommodated in the flux container may be reduced to significantly reduce or prevent a slipping failure of the semiconductor device which may be caused by deep dipping. In addition, the semiconductor device may be prevented from detaching from the head tool which may be caused by deep dipping. In addition, the visibility of the connection terminal may be improved in subsequent processes, resulting in improved workability.

While example embodiments have been shown and described above, it will be apparent to those skilled in the art that modifications and variations could be made without departing from the scope of the present inventive concepts as defined by the appended claims.

What is claimed is:

1. A semiconductor manufacturing apparatus comprising:
a flux container defining an accommodation space, the accommodation space configured to accommodate flux;
a head tool configured to pick up and position a semiconductor device; and
a vibration generator configured to apply vibrations to the flux container.

2. The semiconductor manufacturing apparatus of claim 1, wherein the vibration generator comprises:
a vibration plate having a first surface and a second surface, the second surface opposing the first surface;
a first electrode on the first surface of the vibration plate; and
a second electrode on the second surface of the vibration plate.

3. The semiconductor manufacturing apparatus of claim 2, wherein
the vibration plate comprises a piezoelectric ceramic.

4. The semiconductor manufacturing apparatus of claim 2, wherein
the first surface and the second surface of the vibration plate are an upper surface and a lower surface of the vibration plate, respectively.

5. The semiconductor manufacturing apparatus of claim 2, wherein
the first and second surfaces of the vibration plate are side surfaces of the vibration plate.

6. The semiconductor manufacturing apparatus of claim 1, wherein
the vibration generator is coupled to a lower surface of the flux container.

7. The semiconductor manufacturing apparatus of claim 6, wherein
a height of the vibration generator is substantially equal to or greater than a height from the lower surface of the flux container to a bottom surface of the accommodation space.

8. The semiconductor manufacturing apparatus of claim 1, wherein
the vibration generator is within an internal space of the flux container.

9. The semiconductor manufacturing apparatus of claim 8, wherein
a height of the vibration generator is substantially equal to or greater than a height from an upper surface of the vibration generator to a bottom surface of the accommodation space.

10. The semiconductor manufacturing apparatus of claim 1, wherein
the vibration generator overlaps with an entire bottom surface of the accommodation space.

11. The semiconductor manufacturing apparatus of claim 1, wherein
the vibration generator is included in a plurality of vibration generators,
the plurality of vibration generators are arranged in at least one of a first direction or a second direction,
the first and second direction parallel to a bottom surface of the accommodation space and intersecting each other, the bottom surface of the accommodation space is divided into a plurality of regions, and
each of the plurality of vibration generators overlap with a corresponding region of the regions of the bottom surface of the accommodation space.

12. The semiconductor manufacturing apparatus of claim 11, wherein
the plurality of vibration generators are configured to vibrate at different frequencies to each other.

13. The semiconductor manufacturing apparatus of claim 1, further comprising:
a flux tank configured to supply the flux to the accommodation space and to planarize the supplied flux.

14. The semiconductor manufacturing apparatus of claim 1, wherein
the semiconductor device includes connection terminals on a first surface,
the head tool is configured to pick up the semiconductor device on a surface different from the first surface, and
the connection terminals comprise at least one of a solder ball or a solder bump.

15. A semiconductor manufacturing apparatus comprising:
a flux container configured to accommodate flux;
a vibration generator coupled to the flux container and configured to apply vibrations to the flux container;
a transfer head configured to temporarily accommodate a semiconductor device;
a stage configured to accommodate a base substrate; and
a head tool configured to pick up the semiconductor device from the transfer head and to transfer the semiconductor device between the transfer head, the flux container, and the stage.

16. The semiconductor manufacturing apparatus of claim 15, wherein the vibration generator comprises:
a vibration plate having a first surface and a second surface, the second surface opposing the first surface;
a first electrode on the first surface of the vibration plate; and
a second electrode on the second surface of the vibration plate, and
the vibration plate is configured to generate ultrasonic waves to apply the vibrations to the flux container.

17. The semiconductor manufacturing apparatus of claim 16, wherein
the vibration plate comprises a piezoelectric ceramic.

18. A method of operating a semiconductor manufacturing apparatus, the method comprising:
supplying flux to an accommodation space of a flux container;
applying vibrations to the flux using a vibration generator coupled to the flux container;
dipping a connection terminal of a semiconductor device into the vibrating flux; and
mounting the dipped semiconductor device on a base substrate.

19. The method of claim 18, wherein
the vibration generator comprises a piezoelectric ceramic, and
the vibration generator applies vibrations to the flux using ultrasonic waves generated from the piezoelectric ceramic.

20. The method of claim 18, wherein the dipping the connection terminal of the semiconductor device comprises:
picking up the semiconductor device from a transfer head using a head tool; and
dipping at least a portion of the connection terminal of the semiconductor device into the vibrating flux using the head tool.
